(19) United States
(12) Patent Application Publication
(10) Pub. No.: US 2008/0230464 A1
(43) Pub. Date: Sep. 25, 2008

(54) Two sided conductive filtration media

(76) Inventors: David E. Winstrup, Greer, SC (US); Steven A. Stansell, Spartanburg, SC (US); Alfred R. DeAngelis, Spartanburg, SC (US)

Correspondence Address: Legal Department (M-495), P.O. Box 1926, Spartanburg, SC, 29304, US

(21) Appl. No.: 11/726,579

(22) Filed: Mar. 22, 2007

(51) Int. Cl. B01D 35/06; B03C 3/00; H05K 3/00

(52) U.S. Cl. 210/243; 427/98.4; 96/77

(57) ABSTRACT

A conductive filtration media having a textile substrate (with a defined first side and a second side and a machine and cross-machine direction), where the conductive pattern on the first side is in registration with the conductive pattern on the second side of the textile substrate. The conductive pattern has a plurality of continuous conductive pathways across the textile substrate, the resistivity of the conductive pattern is less than 100 mega ohms when measured on a 2″ by 12″ sample taken in the machine and cross-machine direction of the textile substrate in accordance with test DIN 54 345, and the air permeability of the conductive filtration media is between 1 and 100 cc/cm²/sec as measured by ASTM D737. A conductive air filter made from the conductive filtration media and the method of making the conductive filtration media is also disclosed.

### TECHNICAL FIELD

The present invention generally relates to filtration media that exhibit conductive properties. More particularly, the invention relates to filtration media having two sided conductive patterns in registration.

### BACKGROUND

Filtration media can take many forms, including knit textiles, woven textiles, nonwovens, papers, films and the like. The media can be used in a number of physical orientations within the filtration device. Recent trends in the filtration industry include the use of these media in folded and pleated orientations. As a general definition, the filtration media is the part of the filter device that actually separates the filtered material from the air or liquid matrix.

There are numerous industries and applications requiring filters. These include home, industrial, transportation, and many other application areas. These areas include two general classifications of filtration, those being air filtration and liquid filtration. In some of the applications requiring air filtration, the passage of the air through the filtration media and the collection of the filtrate material may generate a static charge. In severe circumstances this static charge may build up and discharge in an explosive event.

There is a need to have air filtration media capable of dissipating a static charge, while preserving the air permeability of the filtration media. By proper installation of such a media in a filter, the static charges can be dissipated to avoid static build-up which could cause an explosive event. The static dissipative media can be subsequently grounded at specific locations on the assembled filter, or used to dissipate the static charges to a larger surface area, diminishing the possibility of these charges building up to the point of causing an explosive event.

### SUMMARY

The present invention provides advantages and/or alternatives over the prior art by providing a conductive filtration media having a textile substrate (with a defined first side and a second side and a machine and cross-machine direction), where the conductive pattern on the first side is in registration with the conductive pattern on the second side of the textile substrate. The conductive pattern has a plurality of continuous conductive pathways across the textile substrate, the resistivity of the conductive pattern is less than 100 mega ohms when measured on a 2″ by 12″ sample taken in the machine and cross-machine direction of the textile substrate in accordance with test DIN 54 345, and the air permeability of the conductive filtration media is between 1 and 100 cc/cm²/sec (as measured by ASTM D737). A conductive air filter made from the conductive filtration media and the method of making the conductive filtration media is also disclosed.

### BRIEF DESCRIPTION OF THE DRAWINGS

The present invention will now be described by way of example only, with reference to the accompanying drawings which constitute a part of the specification herein and in which:

FIG. 1 is an illustration of the cross-section of a conductive filtration media.

FIG. 2 is a top view of one embodiment of the conductive filtration media.

FIGS. 3A-3C show additional conductive patterns on the conductive filtration media.

FIGS. 4A and 4B show the first conductive pattern on the first side of the textile substrate and the second conductive pattern on the second side of the textile substrate which are in registration with each other.

FIG. 5 shows the first conductive pattern not in registration with the second conductive pattern.

FIG. 6 shows an illustration of one embodiment of a conductive air filter.

FIG. 7 illustrates an enlarged view of the pleated conductive filtration media

### DETAILED DESCRIPTION

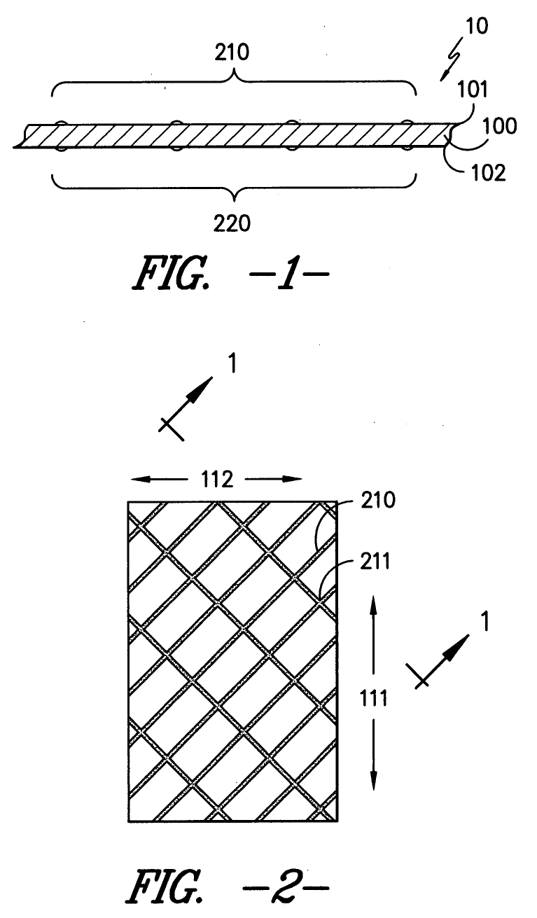

Referring now to FIG. 1, there is shown a cross-sectional view (taken along the line 1 shown in FIG. 2) of one embodiment of the conductive filtration media 10. The conductive filtration media 10 has a textile substrate 100 having a first side 101 and a second side 102. The conductive filtration media 10 additionally has a machine direction 111 and a cross-machine direction 112 as shown in FIG. 2.

The textile substrate 100 may be of any stitch construction suitable to the end use, including by not limited to woven, knitted, non-woven, and tufted textiles, or the like. Woven textiles can include, but are not limited to, satin, twill, basket-weave, poplin, and crepe weave textiles. Jacquard woven structures may be useful for creating more complex electrical patterns. Knit textiles can include, but are not limited to, circular knit, reverse plaited circular knit, double knit, single jersey knit, two-end fleece knit, three-end fleece knit, terry knit or double loop knit, warp knit, and warp knit with or without a microdenier face. The textile substrate 100 may be flat or may exhibit a pile. Nonwoven fabrics or substrates can be formed from many processes such as, for example, meltblowing processes, spunbonding processes, air laying processes, needle punched, and bonded carded web processes. In one embodiment, spunbond nonwovens are tend to have a low cost of manufacture.

The textile substrate 100 is formed of fibers. As used herein fibers shall include continuous strand of textile fibers, spun or twisted textile fibers, textile filaments, or material in a form suitable for knitting, weaving, or otherwise intertwining to form a textile. The term fiber includes, but is not limited to, monofilament fibers, multifilament fibers, staple fibers, or a combination thereof.

The fiber of the textile substrate 100 may be any natural or man-made fiber (mixtures thereof including but not limited to man-made fibers such as polyethylene, polypropylene, polyesters (polyethylene terephthalate, polybutylene terephthalate, polytrimethylene terephthalate, polylactic acid, and the like, including copolymers thereof), nylons (including nylon 6 and nylon 6,6), regenerated cellulosics (such as rayon or Tencel™), elastomeric materials such as Lycra™, high-performance fibers such as the polyaramids, polyimides, PEI, PBO, PBI, PEEK, liquid-crystalline, thermosetting polymers such as melamine-formaldehyde (Basofil™) or phenol-formaldehyde (Kynol™), basalt, glass, ceramic, cotton, coir, bast fibers, proteinaceous materials such as silk, wool, other animal hairs such as angora, alpaca, or vicuna, and blends thereof. In one embodiment, the fibers are polyester continuous filament fibers. It has been found that polyester continuous filament fibers are able to provide the required strength, stability and other performance requirements at a reasonable manufacturing cost.

Referring still to FIG. 1, there is a conductive pattern 210 on the first side 101 of the textile substrate 100 and a second conductive pattern 220 on the second side 102 of the textile substrate 100. The conductive patterns 210 and 220 have a plurality of continuous conductive pathways across the textile substrate 100 in both the machine direction 111 and cross-machine direction 112 as shown in FIG. 2. Having continuous conductive pathways means that there are multiple electrically continuous pathways or elements that extend across the textile substrate 100 in the machine direction 111 and in the cross-machine direction 112. In one embodiment, the conductive patterns are electrically redundant, meaning that there are electric redundancies built into the pattern and that if one line or section of the pattern is disrupted, discontinuous, or otherwise broken, there is still a continuous electrical pathway from one side of the conductive filtration media 10 to the other side in the machine 111 and cross-machine direction 112. As used herein, a line is defined as a continuous conductive path. The lines of the pattern may be substantially straight lines, curved lines, or combinations thereof.

The continuous conductive pathways may form at least one intersection, and they may form a plurality of intersections. As used herein, an intersection is defined as one point having at least 3 lines or pathways radiating from it. The lines of the conductive patterns 210 and 220 typically define an opening not greater than about 3 inches square, and preferably not greater than about 1 inch square. “About three inches square” typically represents a square area with approximately three inches on each side, and “about one inch square” typically represents a square area with approximately 1 inch on each side. For example, when a three inch square is placed on the conductive filtration media 10, it should make contact with the conductive pattern 210 or 220 in at least one location. However, it is foreseeable in some instances that the edges of the fabric may have areas free from the conductive patterns 210, 220 greater than about 3 inches square.

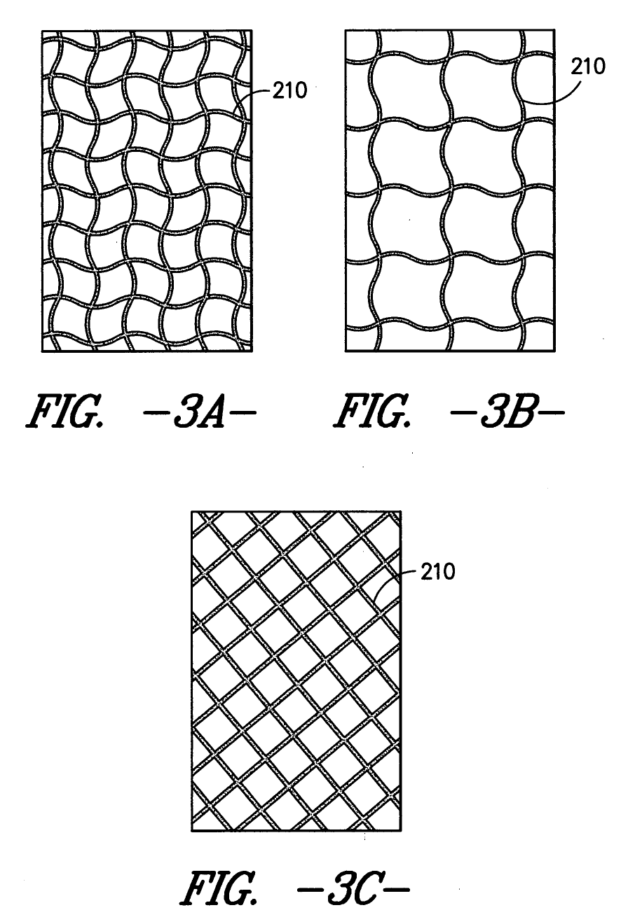

In one embodiment, one or both of the conductive patterns 210, 220 comprise a conductive pattern of a series of lines which intersect each other to form a grid pattern. The grid pattern may be diagonal relative to the machine 111 and cross-machine 112 directions of the textile substrate 100. This is shown, for example, in FIG. 2. In FIG. 2, the conductive pattern 210 on the first side 101 of the conductive filtration media 10 is a diagonal grid pattern having one or more intersections 211. While the pattern is described in regards to the first side 101 of the conductive filtration media 10, the pattern on the second side 102 may have the identical pattern. FIGS. 3A-3C show additional conductive patterns that may be printed on one or both sides of the textile substrate 100. FIGS. 3A and 3B show embodiments where the pattern comprises wavy or curved continuous lines. FIG. 3C shows a grid pattern that is slight skewed, meaning that the entire pattern has been rotated about its center a few degrees (about 1 to 50 degrees). The patterns in FIGS. 3A-3C have been described with regards to the first conductive pattern 210, the patterns may also be used on the second conductive pattern 220. In addition to the continuous lines, some patterns 210 may also contain a number of lines or pattern elements that are not continuous across the media.

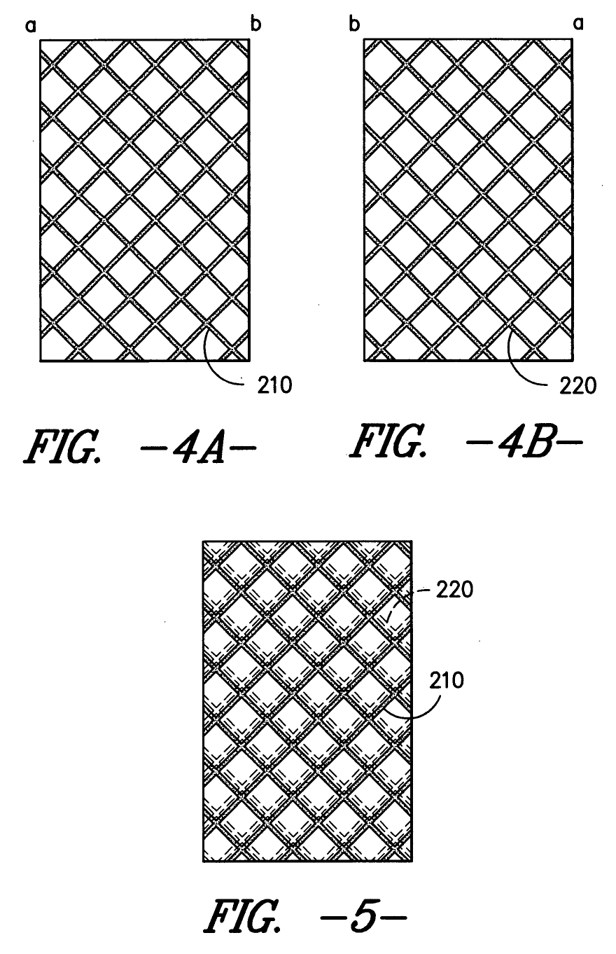

During the application of these patterns it is further important to insure that the two conductive patterns 210, 220 are applied in registration such that both patterns line up directly across from one another on the two sides of the conductive filtration media 10. FIG. 4 shows the first conductive pattern 210 and second conductive pattern 220 that the “a” and “b” corners of the patterns, when printed on the textile substrate 100, are aligned.

The registered application of these two patterns is important for several reasons.

1) Having conductive patterns 210 and 220 in registration produce a more aesthetically appealing media.

2) When conductive patterns 210 and 220 are applied in registration, the conductive material as applied to the media in an aqueous or liquid state will penetrate into the media from both sides. This penetration of the conductive material into the filtration media will enhance conductivity of the media from one side to the other and actually provides an enhanced reduction in the measured resistance of an electrical charge across the media in either the machine 111 or 112 direction. The first conductive pattern 210 is electrically connected to the second conductive pattern 200 through the textile substrate 100.

3) By placing the conductive grid in registration, improved air permeability through the media is achieved by reducing the surface area of the media containing the conductive particles. This allows for the highest possible conductivity while still maintaining the highest level of air permeability through the filtration media.

It is desirous that both the first conductive pattern 210 and the second conductive pattern 220 have exactly the same (meaning identical) pattern in registration with one another.

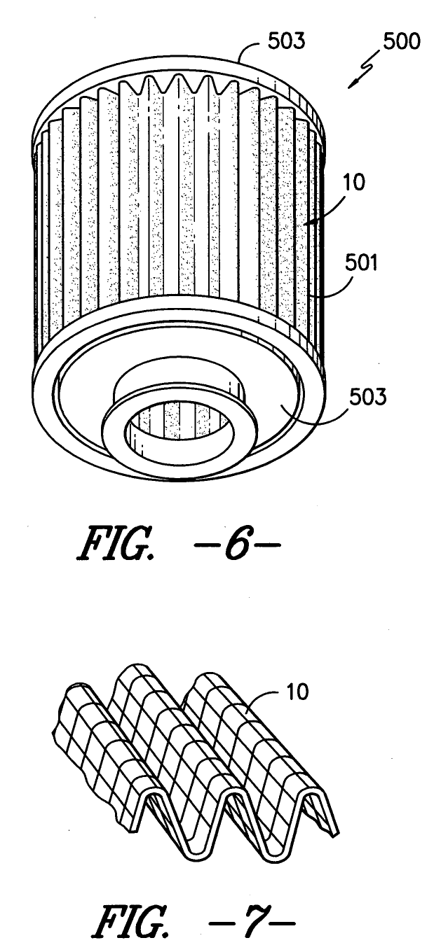

FIG. 5 shows a conductive filtration media 10 with the first conductive pattern 210 on the first side 101 and the second pattern 220 (shown as a dashed line) on the second side 102 of the textile substrate 100, where the first and second conductive patterns 210, 220 are not in registration. As can be seen from FIG. 5, a larger percentage of the area of the conductive filtration media 10 is covered by the conductive patterns, thereby reducing the overall conductivity of the filtration media and reducing the air flow.

In one embodiment, the conductive patterns 210 and 220 comprise a conductive material applied as a paste. The conductive paste generally includes a conducting agent and a binding agent. Preferably, the conducting agent is carbon. The conductive paste may also optionally include a dispersing agent and/or a thickening agent. Additional details on conductive patterns and materials may be found in US Patent Publication 2004/0053552 (Child et al.), incorporated herein in its entirety.

One potentially preferred, non-limiting conducting agent is graphite, such as, for example, Timrex® SFG available from Timcal Ltd. of Switzerland. Other conducting agents include, for example, Zelec® (available from Milliken Chemical of Spartanburg, S.C.); carbon particles; intrinsically conductive polymers; metal; metal oxides; metal shavings; fibers or beads coated with graphite, carbon particles, intrinsically conductive polymers, metal, metal oxides, or metal shavings; and the like; and combinations thereof. The conducting agent may be comprised of particles of various shapes, such as spheres, rods, flakes, and the like, and combinations thereof. The conducting agent may be comprised of conducting particles having a size between about 0.1 and about 100 microns, or more preferably having a size between about 1 and about 5 microns. Conducting agents may be characterized by having an aspect ratio number which is the ratio of a conducting particle's length divided by its width. For example, a perfect sphere has an aspect ratio of one. The longer the particle (i.e., the more rod-like the particle), the higher the aspect ratio. Generally, for a conducting agent having a high aspect ratio, less conducting agent is needed to provide the same electrical conductivity in an object, such as the present invention, when compared to a conducting agent made of a similar conducting agent but having a lower aspect ratio.

The conductive paste may include a binding agent which typically provides a non-conducting matrix which holds the conducting particles together and helps them bond to the textile substrate 100. Binding agents include water-borne latexes, solvent-borne polymer systems, liquid rubbers, thermoplastic hot melts, thermoset hot melts, multi-component reactive polymers, and the like, and combinations thereof. More specifically, binding agents may be acrylic latex, polyurethane, silicone, polyvinyl chloride latex, and the like, or combinations thereof. Binders generally vary, for example, in elongation and flex modulus properties which may affect the hand, drape, and stretch properties of the coated fabric. Thus, the selection of a particular binder for the conductive paste may depend on the end-use application of the conductive filtration media 10. It may be preferable that the binding agent has an elongation at break equal to or greater than about 80 percent of the elongation at break of the fabric. It may be preferable that the binding agent has a glass transition temperature equal to or less than about 0° C. and a melting temperature equal to or greater than about 100° C. Acrylic binders are preferred for their commercial availability and flexibility.

Preferably, the conductive paste has a viscosity of between 10,000 and 40,000 centipoise as measured by an LVF viscometer with a #4 spindle at 6 rpm. This viscosity range has been found to produce a conductive paste that is easily printed onto the textile substrate without excessive bleeding. By selecting the appropriate paste viscosity, penetration through the filter media can be controlled, as well as pattern definition (or amount of bleed of the printed pattern). In one embodiment, the conductive patterns 210 and 220 cover about 15 to 25 percent of the surface area of the first side 101 and second side 102 of the textile substrate 100. It has been found that this range of coverage produces conductive patterns with an appropriate amount of conductivity and a conductive filtration media 10 with adequate air permeability.

In one embodiment, the conductive pastes applied as the conductive pattern 210 and 220 absorb through the textile substrate 100 and are electrically connected through the textile substrate 100. This increases the conductivity of conductive filtration media 10. This penetration of the conductive material into the filtration media will enhance conductivity of the media from one side to the other and actually provides an enhanced reduction in the measured resistance of an electrical charge across the media in either the machine 111 or 112 direction.

The conductive filtration media 10 has a surface resistance in a range less than 100 mega ohms (10⁸ ohms) when measured on a 2″ by 12″ sample taken in the machine and cross-machine direction of the conductive filtration media 10 in accordance with test DIN 54 345. It has been found that this range provides good discharge of static build up on air filters. The air permeability of the conductive filtration media 10 is between 1 and 100 cc/cm²/sec as measured by ASTM D737. This air permeability is effective for use in filtration applications.

The process for forming the conductive filtration media 10 includes forming textile substrate 100 having a first side 101 and a second side 102 and printing a first conductive pattern 210 on the first side 101 and a second conductive pattern 220 on the second side 102 of the textile substrate. The first conductive pattern 210 and the second conductive pattern 220 are in registration with one another and the conductive patterns 210, 220 include a plurality of continuous conductive pathways across the textile substrate.

The printing of the conductive patterns 210 and 220 onto the textile substrate 100 may be of any known method such as transfer printing, lithographic printing, ink jet printing, digital printing, and the like. One potentially preferred non-limiting method for applying the conductive coating to the fabric is to apply the coating as a paste onto the fabric through screen printing. Screen printing techniques have been available for many years as a way of selectively producing a pattern on a fabric by forcing a paste through holes in a screen. For example, U.S. Pat. No. 4,365,551 to Horton; U.S. Pat. No. 4,854,230 to Niki et al.; U.S. Pat. No. 5,168,805 to Kasanami et al.; U.S. Pat. No. 5,493,969 to Takahashi et al.; and U.S. Pat. No. 6,237,490 to Takahashi et al. each describe various screen printing methods and apparatus, and are herein incorporated by reference. For purposes of the present invention, a conductive paste may be forced through a specially prepared screen onto a substrate such as a fabric. The screen typically has areas in which the mesh has been blocked. These areas, which remain impervious to the conductive paste, correspond to patterned areas on the fabric in which no conductive coating is desired.

In one embodiment, the textile substrate is fed into a nip formed by two screen printing rollers and the first conductive pattern 210 and second conductive pattern 220 are printed in registration simultaneously. Certain conductive patterns, such as the skewed grid-like pattern shown in FIG. 3C, have the advantage that the rollers can be adjusted in just the cross-machine direction to register the first and second conductive patterns 210, 220 in both the machine and cross-machine direction. There are additional patterns that may be selected for the first and second conductive patterns 210, 220 that need the printing rollers to be adjusted only in either the machine or cross-machine direction to gain alignment of the two conductive patterns 210 and 220 in both the machine and cross-machine direction. Adjusting the rollers in the cross-machine direction is a much simpler operation that changing the speed of the rollers relative to one another. When the textile substrate is introduced into the nip, one or more squeegees in the screen force a conductive material through the holes in the screen, thereby forming a printed pattern of conductive pattern on the textile substrate 100.

The conductive filtration media 10 next typically moves in a continuous fashion to a drying oven where the conductive coating is dried. Drying can be accomplished by any technique typically used in manufacturing operations, such as dry heat from a tenter frame, microwave energy, infrared heating, steam, superheated steam, autoclaving, or the like, or any combination thereof. Typically, the fabric may be dried and/or cured for between about 30 seconds and about 5 minutes at a temperature of between about 250 and about 375 degrees F. Drying typically removes the water or solvent from the binder formulation in the conductive coating. The amount of conductive coating required depends generally on the pattern chosen for the fabric, and this is typically determined by the fabric's end-use. The drying temperatures may vary depending on the exact chemistry and/or viscosity of the conductive coating employed in the application process. In one embodiment, the textile substrate is heated to a temperature of between 270 and 210° F. prior to printing on the textile substrate 100. This serves to prepare the substrate for paste application and allows the printing material to flow more easily onto the media without clogging the print screens.

The conductive filtration media 10 of the invention may be used in many applications where static charge needs to be dissipated and air needs to be filtered. One application of the conductive filtration media 10 is in a conductive air filter cartridge 500 as shown in FIG. 6. FIG. 6 illustrates a conductive air filter cartridge 500 made with the conductive filtration media 10 of the invention pleated between two end caps 503. The conductive filtration media 10 is grounded. This may be accomplished, for example, by a grounding wire 501 is connected from conductive filtration media 10 to a ground (not shown) or the conductive filtration media 10 electrically connected to the end cap(s) 503 which are connected to a ground. FIG. 7 illustrates an enlarged view of the pleated conductive filtration media 10.

### EXAMPLES

### Example 1 was a conductive filtration media printed on both sides of

the textile substrate with an identical conductive pattern, but the patterns were not in registration as can be seen, for example, in FIG. 5. The textile substrate used was a spunbond nonwoven textile of continuous polyester fibers.

The spunbond nonwoven textile was then screen printed on both sides of the textile substrate using a diamond pattern. The conductive pattern was formed using a conductive paste of graphite carbon and an acrylic binder to have a viscosity of 50,000 centipoise as measured by an LVF viscometer with a #4 spindle at 6 rpm. The conductive patterns were not in registration, but off-set from one another by approximately 10 millimeters. The conductive pattern had line widths of approximately 1 millimeter and the conductive paste covered approximately 20% of the surface area of the first and second surfaces of the filtration media.

Example 2 was a conductive filtration media printed on both sides of the textile substrate with the conductive patterns in registration. Example 2 was formed using the same materials and process as Example 1, except that the patterns on the two sides were identical and in registration as shown, for example, in FIGS. 4A and B.

Examples 1 and 2 were tested for a variety of physical parameters as shown in the table below.

| | Electrical | | |
|---|---|---|---|
| | resistance* | Air permeability | Patterns on opposite sides |
| | (ohms) | (cc/cm²/sec) | electrically connected? |
| Example 1 | 370 | 6.3 | No |
| Example 2 | 390 | 8.0 | Yes |

*measured on a 2″ by 12″ sample taken in the machine and cross-machine direction of the conductive filtration media 10 in accordance with test DIN 54 345.

As can be seen from the results in the table above, when the two conductive patterns on the first and second side of the textile substrate are in registration, the air permeability increases and the electrical resistance remained essentially constant. This decrease in resistivity can be used to create a more conductive filtration media or may be used to be able to reduce the coverage (or line width) of the conductive pattern and still maintain adequate electrical resistance.

While the present invention has been illustrated and described in relation to certain potentially preferred embodiments and practices, it is to be understood that the illustrated and described embodiments and practices are illustrative only and that the present invention is in no event to be limited thereto. Rather, it is fully contemplated that modifications and variations to the present invention will no doubt occur to those of skill in the art upon reading the above description and/or through practice of the invention. It is therefore intended that the present invention shall extend to all such modifications and variations as may incorporate the broad aspects of the present invention within the full spirit and scope of the invention.

What is claimed is:

1. A conductive filtration media comprising:
a textile substrate having a first side and a second side and a machine and cross-machine direction, wherein the first side comprises a first conductive pattern and the second side comprises a second conductive pattern, wherein the first conductive pattern is in registration with the second conductive pattern, and
wherein the conductive pattern comprises a plurality of continuous conductive pathways across the textile substrate; and,
wherein the resistivity of the first conductive pattern and second conductive pattern is less than 100 mega ohms when measured on a 2″ by 12″ sample taken in the machine and cross-machine direction of the textile substrate in accordance with test DIN 54 345, and wherein the air permeability of the conductive filtration media is between 1 and 100 cc/cm²/sec as measured by ASTM D737.

2. The conductive filtration media of claim 1, wherein the first conductive pattern and the second conductive pattern comprise the same pattern.

3. The conductive filtration media of claim 1, wherein the textile substrate comprises a nonwoven substrate.

4. The conductive filtration media of claim 1, wherein the textile substrate comprises polyester continuous filament fibers.

5. The conductive filtration media of claim 1, wherein the first and second conductive patterns comprise a conductive material.

6. The conductive filtration media of claim 5, wherein the conductive material comprises carbon and a binder.

7. The conductive filtration media of claim 6, wherein the binder comprises an acrylic compound.

8. The conductive filtration media of claim 5, wherein the conductive material has a viscosity of between 10,000 and 100,000 centipoise measured by an LVF viscometer with a #4 spindle at 6 rpm.

9. The conductive filtration media of claim 1, wherein the plurality of continuous conductive pathways across the textile substrate are electrically redundant.

10. The conductive filtration media of claim 1, wherein the first conductive pattern covers about 15 to 25% of the surface area of the first side of the textile substrate and the second conductive pattern covers about 15 to 25% of the surface area of the second side of the textile substrate.

11. The conductive filtration media of claim 1, wherein the first conductive pattern is electrically connected to the second conductive pattern.

12. A process for forming a conductive filtration media comprising:
forming textile substrate having a first side and a second side and a machine and cross machine direction;
printing a first conductive pattern on the first side of the textile substrate and printing a second conductive pattern on the second side of the textile substrate, wherein the first conductive pattern is in registration with the second conductive pattern, and wherein the conductive pattern comprises a plurality of continuous conductive pathways across the textile substrate;
drying the first conductive pattern and the second conductive pattern; and,
wherein the resistivity of the first conductive pattern and second conductive pattern is less than 100 mega ohms when measured on a 2″ by 12″ sample taken in the machine and cross-machine direction of the textile substrate in accordance with test DIN 54 345 after drying, and wherein the air permeability of the conductive filtration media is between 1 and 100 cc/cm²/sec as measured by ASTM D737 after drying.

13. The process of claim 12, wherein the first conductive pattern and the second conductive pattern comprise the same pattern.

14. The process of claim 12, wherein the textile substrate is heated to a temperature of between about 270 and 310° F. prior to printing the conductive pattern.

15. The process of claim 12, wherein printing the first conductive pattern and the second conductive pattern comprises screen printing.

16. The process of claim 12, wherein the first conductive pattern and the second conductive pattern are printed simultaneously.

17. The process of claim 12, wherein the screen printing comprises passing the textile substrate between a nip formed by two print rollers, wherein the two print rollers print on the first and second sides of the textile substrate simultaneously.

18. The process of claim 17, wherein the first and second conductive patterns are selected such that the first and second print rollers are adjusted in either the cross-machine direction or the machine direction of the textile substrate media to register the conductive pattern on the first and second side of the textile substrate in both the cross-machine direction and machine direction of the textile substrate media.

19. The process of claim 12, wherein the textile substrate comprises a spunbond nonwoven substrate.

20. The process of claim 12, wherein the conductive pattern comprises a conductive material comprising carbon and a binder.

21. The process of claim 20, wherein the conductive material has a viscosity of between 10,000 and 100,000 centipoise measured by an LVF viscometer with a #4 spindle at 6 rpm.

22. The process of claim 12, wherein the plurality of continuous conductive pathways across the textile substrate are electrically redundant.

23. The process of claim 12, wherein the first conductive pattern covers about 15 to 25% of the surface area of the first side of the textile substrate and the second conductive pattern covers about 15 to 25% of the surface area of the second side of the textile substrate.

24. A conductive air filter cartridge comprising:
two end caps;
a pleated conductive filtration media disposed between the end caps, wherein the pleated conductive filtration media is grounded;
wherein the conductive filtration media comprises a textile substrate having a first side and a second side and a machine and cross-machine direction, wherein the conductive pattern on the first side is in registration with the conductive pattern on the second side of the textile substrate;
wherein the conductive pattern comprises a plurality of continuous conductive pathways across the textile substrate, wherein the resistivity of the conductive pattern is less than 100 mega ohms when measured on a 2″ by 12″ sample taken in the machine and cross-machine direction of the textile substrate in accordance with test DIN 54 345, and wherein the air permeability of the conductive filtration media is between 1 and 100 cc/cm²/sec as measured by ASTM D737.
